(19) United States
(12) Patent Application Publication
(10) Pub. No.: US 2026/0076014 A1
(43) Pub. Date: Mar. 12, 2026

(54) ELECTRONIC DEVICE AND REWORKING METHOD FOR THE ELECTRONIC DEVICE

(71) Applicant: AUO Corporation, Hsinchu City (TW)

(72) Inventors: YIN-TING LEE, Hsinchu City (TW); Hui-Chuan CHEN, Hsinchu City (TW); Bo-Yuan SU, Hsinchu City (TW)

(21) Appl. No.: 18/968,192

(22) Filed: Dec. 4, 2024

(30) Foreign Application Priority Data
Sep. 6, 2024 (TW) 113133858

(51) Int. Cl. H10H 29/85; H05K 1/18

(52) U.S. Cl. CPC H10H 29/857; H05K 1/189

(57) ABSTRACT

An electronic device includes a light emitting module having a light source module, a back frame configured to support the light source module, at least one stretch release adhesive tape, and a circuit substrate. The back frame has at least one through hole. The at least one stretch release adhesive tape is divided into a first section and a second section along an extending direction, and passes through the at least one through hole to be folded, such that the first section and the second section are respectively located on different sides of the at least one through hole and attached on different surfaces of the back frame facing different directions. At least a portion of the first section adheres and bonds the light source module and the back frame, and at least a portion of the second section adheres and bonds the back frame and the circuit substrate.

### CROSS-REFERENCE TO RELATED PATENT APPLICATION

This non-provisional application claims priority to and the benefit of, pursuant to 35 U.S.C. § 119(a), patent application Serial No. 113133858 filed in Taiwan on Sep. 6, 2024. The disclosure of the above application is incorporated herein in its entirety by reference.

Some references, which may include patents, patent applications and various publications, are cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference were individually incorporated by reference.

### FIELD

The present disclosure relates to an electronic device, and in particular to an electronic device having a stretch release adhesive tap adhering and bonding a circuit substrate.

### BACKGROUND

The background description provided herein is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

In recent years, various electronic devices, such as display devices, have been widely applied across numerous fields and play an essential role in modern society. To meet various application needs and enable various functionalities, an electronic device may include numerous system modules and supporting components. In addition, to supply power or provide electrical control and regulation, the electronic device may further include circuit components that electrically connect different system modules or electrically interconnect with each other. Therefore, as the complexity or sophistication of various components and/or assemblies increase, challenges in the assembly, disassembly and reworking of the electronic device also progressively escalate.

As modern electronic device configurations grow increasingly complex or sophisticated, the assembly, disassembly and reworking processes for the electronic device become correspondingly complicated, time-consuming and labor-intensive. Further, during disassembly and reworking, it may be easily to cause unintended damage or degradation to various components and assemblies, which adversely affects the reparability and reusability of the components and assemblies. However, with development of the technology and the rise of environmental awareness, how to enhance the reparability and reusability of the components and assemblies of the electronic device has become a widely discussed issue. To support a circular economy, reduce resource consumption and mitigate environmental damage, developing improved electronic device configurations and the corresponding disassembly and reworking methods has become a focus in modern technological development. In particular, the trend in research and development is toward simplifying or improving the reworking process to enhance the reparability and reusability of the components and assemblies of the electronic device, thereby conserving and recycling valuable resources.

### SUMMARY

### Technical Means for Resolving the Problem

To resolve the deficiencies, an electronic device according to one embodiment of the present disclosure is proposed, including: a light emitting module, having a light source module; a back frame, configured to support the light source module, and having at least one through hole; at least one stretch release adhesive tape, respectively divided into a first section and a second section along an extending direction, and passing through the at least one through hole to be folded, such that the first section and the second section are respectively located on different sides of the at least one through hole and attached on different surfaces of the back frame facing different directions, wherein at least a portion of the first section adheres and bonds the light source module and the back frame; and a circuit substrate, wherein at least a portion of the second section adheres and bonds the back frame and the circuit substrate.

A reworking method for the electronic device according to another embodiment of the present disclosure is proposed, including the following steps: disassembling the circuit substrate from the back frame, and exposing a predetermined region of the second section of the at least one stretch release adhesive tape; and stretching the predetermined region to at least partially reduce an adhesiveness of the first section of the at least one stretch release adhesive tape connected to the predetermined region, thereby separating the light source module and the back frame.

### Effect Compared to Related Art

Based on the embodiments of the present disclosure, the electronic device and the reworking method for the same may use the stretch release adhesive tape to position at least a portion of the light emitting module and the circuit substrate, thereby simplifying or reducing the positioning components of the electronic device. In addition, based on the embodiments of the present disclosure, the electronic device and the reworking method for the same may further enhance reworking convenience while minimizing or avoiding changes to the configuration of various system modules, and reduce or prevent potential damages to the system modules or components during reworking. Therefore, the electronic device and the reworking method for the same according to the embodiments of the present disclosure may offer a more integrated positioning structure and reduce disassembly difficulty, thus improving the retention rate of the system modules or components during reworking, thereby enhancing the repairability and reusability of the system modules or components, and further facilitating the circular economy.

These and other aspects of the present disclosure will become apparent from the following description of the embodiment taken in conjunction with the following drawings, although variations and modifications therein may be effected without departing from the spirit and scope of the novel concepts of the disclosure.

### BRIEF DESCRIPTION OF THE DRAWINGS

The accompanying drawings illustrate one or more embodiments of the disclosure and together with the written description, serve to explain the principles of the disclosure. Wherever possible, the same reference numbers are used throughout the drawings to refer to the same or like elements of an embodiment, and wherein:

FIGS. 1 and 2 are exploded schematic views of an electronic device according to one embodiment of the present disclosure.

FIG. 3 is an exploded schematic view of assembling an electronic device according to one embodiment of the present disclosure.

FIG. 4 is a plain schematic view of the assembly configurations on a back surface of a bottom plate of a back frame in the assembling process of the electronic device according to one embodiment of the present disclosure.

FIG. 5 is a plain schematic view of the configuration of adhering and bonding the circuit substrate on the back surface of the bottom plate of the back frame of the electronic device according to one embodiment of the present disclosure.

FIG. 6 is an exploded schematic view of assembling an electronic device according to another embodiment of the present disclosure.

FIG. 7 is a plain schematic view of the configuration of adhering and bonding the circuit substrate on the back surface of the bottom plate of the back frame of the electronic device according to another embodiment of the present disclosure.

FIG. 8 is a flowchart of a reworking method for disassembling the electronic device according to one embodiment of the present disclosure.

FIG. 9 is a schematic view of disassembling the circuit substrate in the reworking method for the electronic device according to one embodiment of the present disclosure.

FIG. 10 is an enlarged schematic view of a region W of FIG. 9 according to one embodiment of the present disclosure.

FIG. 11 is a schematic view of disassembling the circuit substrate and the predetermined functional module connected thereto in the reworking method for the electronic device according to one embodiment of the present disclosure.

FIG. 12 is a schematic view of a process of stretching the predetermined region on the back surface of the bottom plate of the back frame to disassemble the stretch release adhesive tape according to one embodiment of the present disclosure.

FIG. 13 is a schematic view of stretching the predetermined region on the back surface of the bottom plate of the back frame to disassemble the stretch release adhesive tape and the first flexible circuit board according to one embodiment of the present disclosure.

FIG. 14 is a schematic view of disassembling the stretch release adhesive tape and the light source module on the front surface of the bottom plate of the back frame according to one embodiment of the present disclosure.

FIG. 15 is a schematic view of disposing the stretch release adhesive tape on the front surface of the bottom plate of the back frame according to yet another embodiment of the present disclosure.

FIG. 16 is a schematic view of disposing the stretch release adhesive tape on the front surface of the bottom plate of the back frame according to a further embodiment of the present disclosure.

FIG. 17 is a schematic view of removing a first portion of the release film to expose the stretch release adhesive tape for attaching the light source module according to one embodiment of the present disclosure.

FIG. 18 is a schematic view of removing a second portion of the release film to expose the stretch release adhesive tape for attaching the circuit substrate and/or the first flexible circuit board according to one embodiment of the present disclosure.

### DETAILED DESCRIPTION

The following will describe various embodiments, which those skilled in the relevant field, when referring to the descriptions along with the accompanying drawings, should easily understand the spirit and principles of the present disclosure. Although specific embodiments are provided in detail, these embodiments are intended for illustrative purposes only and should not be considered restrictive or exhaustive in any aspect. Accordingly, for those skilled in the art, various modifications and alterations of the present disclosure should be evident and easily achievable without departing from its spirit and principles.

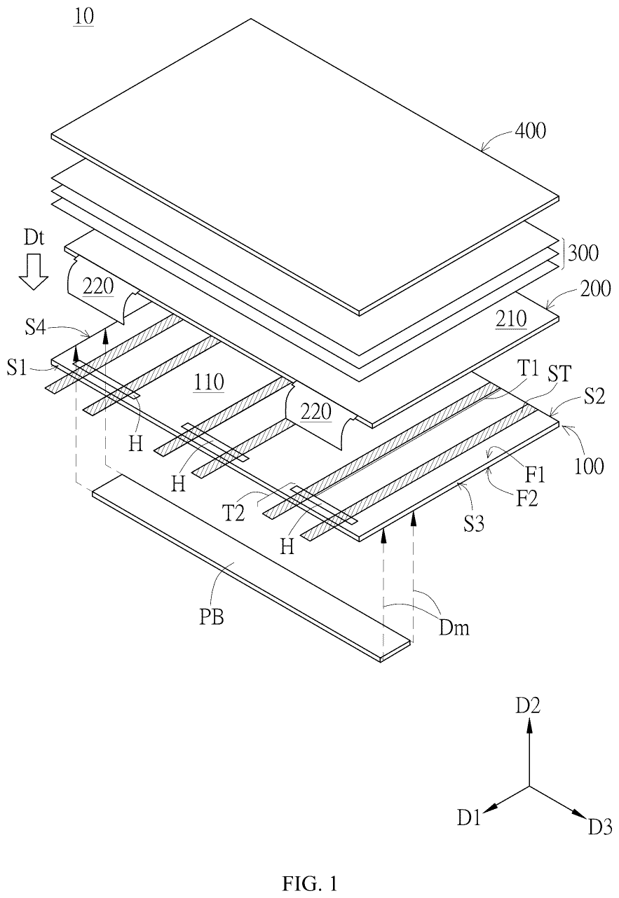

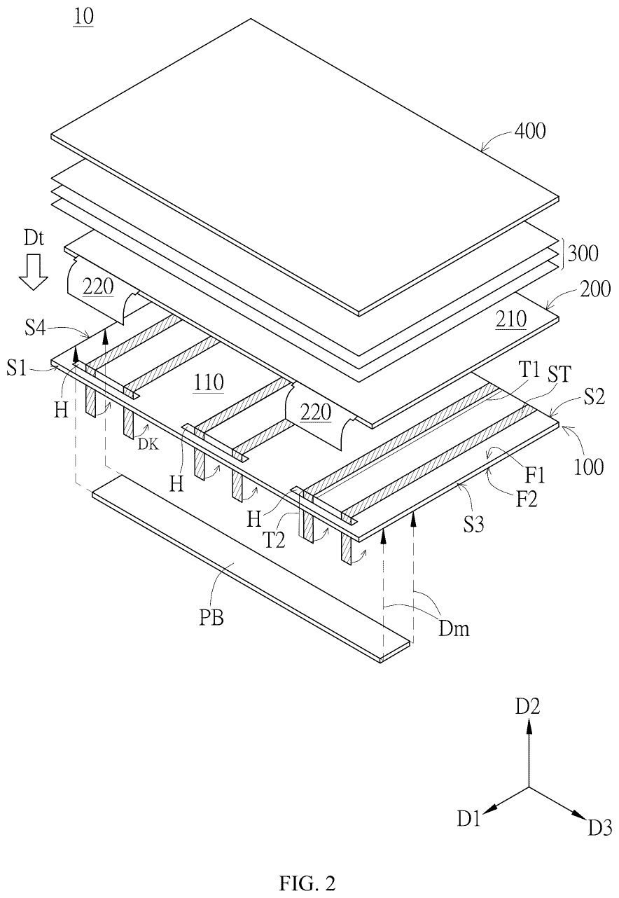

Referring to FIGS. 1 and 2, an electronic device 10 according to one embodiment of the present disclosure may include a back frame 100, a light emitting module 200, at least one stretch release adhesive tape ST, and a circuit substrate PB (such as a printed circuit board). Further, according to different embodiment and based on the expected usage, the electronic device 10 may further include a functional module 400 configured to facilitate a predetermined function, such as a display module configured to facilitate a display function, or a touch control module configured to facilitate a touch control function, without being limited thereto. In addition, one or more layers of functional films may be provided, such as disposing one or more layers of optical films 300 corresponding to the display module, without being limited thereto. According to various embodiments of the present disclosure, other functional modules or further film layers or configurations applicable and integrated in the electronic device 10 may have more variations, and these possible applications and modifications should be readily understood by those skilled in the art and are thus not hereinafter reiterated.

According to one embodiment of the present disclosure, the light emitting module 200 may have a light source module 210 configured with a light emitting source and capable of emitting light, and a first flexible circuit board 220 electrically connected to the light source module 210. For example, according to certain embodiments, the light emitting source may be a mini LED or a micro LED, which are merely exemplary examples, and other embodiments of the present disclosure are not limited thereto. In addition, according to certain embodiments, the light source module 210 may be, for example, a direct type light emitting panel, and is configured to emit light toward a direction substantially opposite to the back frame 100. For example, if the functional module 400 is a display module, the light source module 210 may be a direct type light emitting panel configured to supply light to the display module. However, the description is merely an exemplary example, and the configurations and details of the light source module 400 in other embodiments of the present disclosure are not limited thereto.

The back frame 100 may be configured to support the light source module 210 and/or other structures or modules on the light source module 210, such as the functional module 400, and the stretch release adhesive tape ST may be used to adhere and bond the light source module 210 and the back frame 100. Specifically, according to various embodiments of the present disclosure, the stretch release adhesive tape ST is a tape having adhesiveness on both sides, and its adhesiveness may be at least partially reduced when being stretched or pulled. As shown in FIGS. 1 and 2, the at least one stretch release adhesive tape ST may be divided into a first section T1 and a second section T2 along its own extending direction. The back frame 100 may have at least one through hole H. For example, as shown in FIG. 1, the back frame 100 may have a plurality of through holes H along a first side edge S1, and the through holes H may be correspondingly positioned at locations where the at least one stretch release adhesive tape ST extends and passes. Thus, as shown in FIG. 2, the at least one stretch release adhesive tape ST may pass through the at least one through hole H to be folded along a folding direction DK, such that the first section T1 and the second section T2 may be respectively located on different sides of the at least one through hole H and attached on different surfaces of the back frame 100 facing different directions.

Specifically, according to the present embodiment, the back frame 100 may have at least one bottom plate 110, and the bottom plate 110 has a front surface F1 facing toward the light source module 210 and a back surface F2 away from the light source module 210. According to the present embodiment, as shown in FIGS. 1 and 2, the light source module 210 may be installed on the front surface F1 of the bottom plate 110 of the back frame 100 along an installation direction Dt, and correspondingly, the circuit substrate PB may be installed on the back surface F2 of the bottom plate 110 of the back frame 100 based on an installation direction Dm. Therefore, at least a portion of the first section T1 may adhere and bond the light source module 210 and the back frame 100 (e.g., the bottom plate 110) on the front surface F1, and at least a portion of the second section T2 may adhere and bond the back frame 100 (e.g., the bottom plate 110) and the circuit substrate PB on the back surface F2.

As described above, by pre-providing the stretch release adhesive tape ST to pass through the at least one through hole H to be folded with different sections, the first section T1 and second section T2 of each stretch release adhesive tape ST may adhere and bond the light source module 210 and the circuit substrate PB to different surfaces of the back frame 100. Thus, according to the present embodiment, a relatively simplified positioning arrangement may be used to simultaneously position the light source module 210 and the circuit substrate PB, thereby reducing the cost and process of providing other positioning components and improving the integration of the overall structure. In addition, this can also simplify the disassembly and reworking processes for various components or modules, such that the disassembly and reworking become more convenient and reliable.

In addition, it should be noted that although the embodiment described above and illustrated in the accompanying drawings shows that the back frame 100 has only the bottom plate 110, those skilled in the art should understand that the back frame 100, which is used to place and house the components and modules such as the light source module 210, may have structures other than the bottom plate 110. For example, according to a predetermined design and configuration, the back frame 100 may also have a side wall portion protruding from the front surface F1 of the bottom plate 110. Therefore, those skilled in the art will understand these possible modifications and variations, and the details thereof are not further reiterated herein.

According to certain embodiments, when the area of the light source module 210 is greater than the area of the circuit board PB, the length of the first section T1, which is used to attach the light source module 210, may be greater than the length of the second section T2, which is used to attach the circuit substrate PB, thereby facilitating more secure adhesiveness of the larger light source module 210. In addition, according to certain other embodiments of the present disclosure, the circuit substrate PB may be disposed relatively close to the through hole H without overlapping with the through hole H, such that, on the premise of being able to adhere to the circuit board PB, the length of the second section T2 of the stretch release adhesive tape ST passing through the through hole H and folded may be reduced.

Further, according to certain embodiments, to provide sufficient stretch release adhesive tapes ST through a limited number of through holes H and enhance the adhering and bonding strength, the quantity of the stretch release adhesive tape ST passing through each individual through hole H may not be limited to one. That is, the quantity of the stretch release adhesive tapes ST may be greater than the quantity of the through holes H. For example, as shown in FIGS. 1 and 2, in the present embodiment, two stretch release adhesive tapes ST may be provided for each through hole H. However, this is merely an exemplary example, and other variations may exist according to other embodiments of the present invention. For example, the quantity of the through holes H may be the same as the quantity of the stretch release adhesive tapes ST, such that each through hole H corresponds to one stretch release adhesive tape ST. Alternatively, there may be additional through holes H on the back frame 100 for other purposes, or the same through hole H may serve multiple functions other than accommodating the stretch release adhesive tapes ST, such that certain individual through holes H may either not have corresponding stretch release adhesive tape ST, or different through holes H may have different quantities of the stretch release adhesive tapes ST.

According to certain embodiments, referring to FIGS. 1 and 2, the bottom plate 110 may have a first side edge S1 and a second side edge S2 opposite to each other, as well as a third side edge S3 and a fourth side edge S4 opposite to each other. Herein, a first direction D1 may be defined as the direction from the second side edge S2 toward the first side edge S1, a second direction D2 may be defined as the direction perpendicular to the first direction D1 and facing away from the bottom plate 110 toward the light source module 210, and a third direction D3 may be defined as the direction from the fourth side edge S4 toward the third side edge S3. On the back frame 100, the at least one through hole H may extend individually along the third direction D3 relatively close to the first side edge S1 along a portion of the first side edge S1, and the at least one stretch release adhesive tape ST may extend along the first direction D1 from the second side edge S2 toward the first side edge S1 on the front surface F1 of the bottom plate 110 away from the circuit substrate PB. As described above, the at least one stretch release adhesive tape ST may extend along the first direction D1, thereby passing through the at least one through hole H disposed along the first side edge S1 to be folded over to the back surface F2 of the bottom plate 110, where the circuit substrate PB is to be installed.

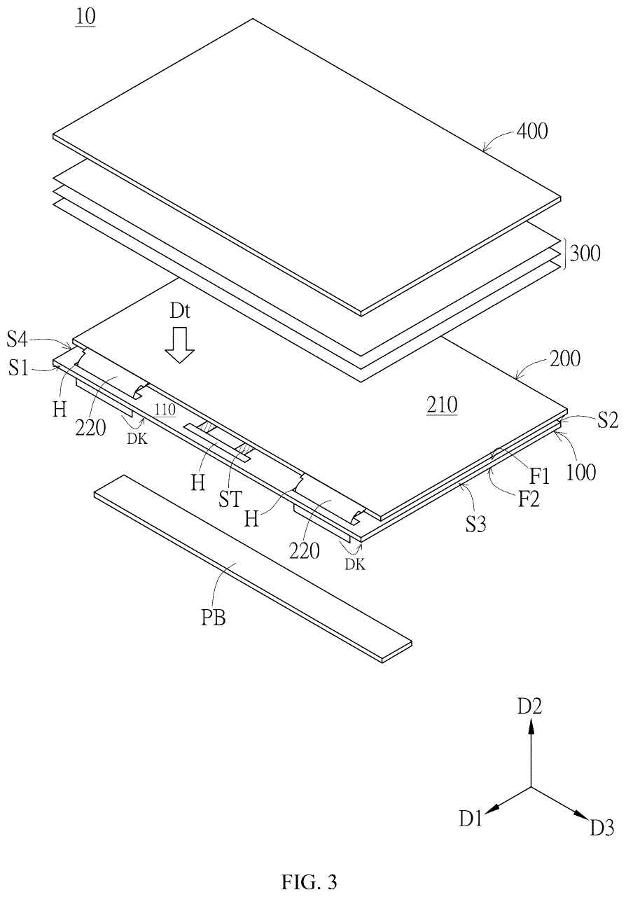

Next, referring to FIGS. 1, 2 and 3, according to this embodiment, when the light source module 210 is installed on the front surface F1 of the bottom plate 110 along the installation direction Dt, the first flexible circuit board 220 electrically connected to the light source module 210 may, similarly to the stretch release adhesive tape ST, pass through the at least one through hole H to be folded along the folding direction DK. According to some embodiments, the first flexible circuit board 220 may conform to the stretch release adhesive tape ST and bend to correspond to the folding direction DK of the stretch release adhesive tape ST. Thus, the light source module 210 and the at least one first flexible circuit board 220 may be located on different sides of the at least one through hole H. For example, the light source module 210 and the at least one first flexible circuit board 220 may be located respectively on the front surface F1 and the back surface F2 of the bottom plate 110.

According to certain embodiments, in the configuration, the quantity of the through holes H may be greater than the quantity of the first flexible circuit boards 220. For example, some of the through holes H may individually be correspondingly configured with one first flexible circuit board 220, and some other through holes H may not have a first flexible circuit board 220 passing therethrough, and instead are configured with only the stretch release adhesive tapes ST passing therethrough, such that the quantity of the through holes H is greater than the quantity of the first flexible circuit boards 220. However, this is merely an exemplary example, and according to other embodiments of the present invention, each through hole H may be correspondingly configured with one or more first flexible circuit boards 220 to be folded.

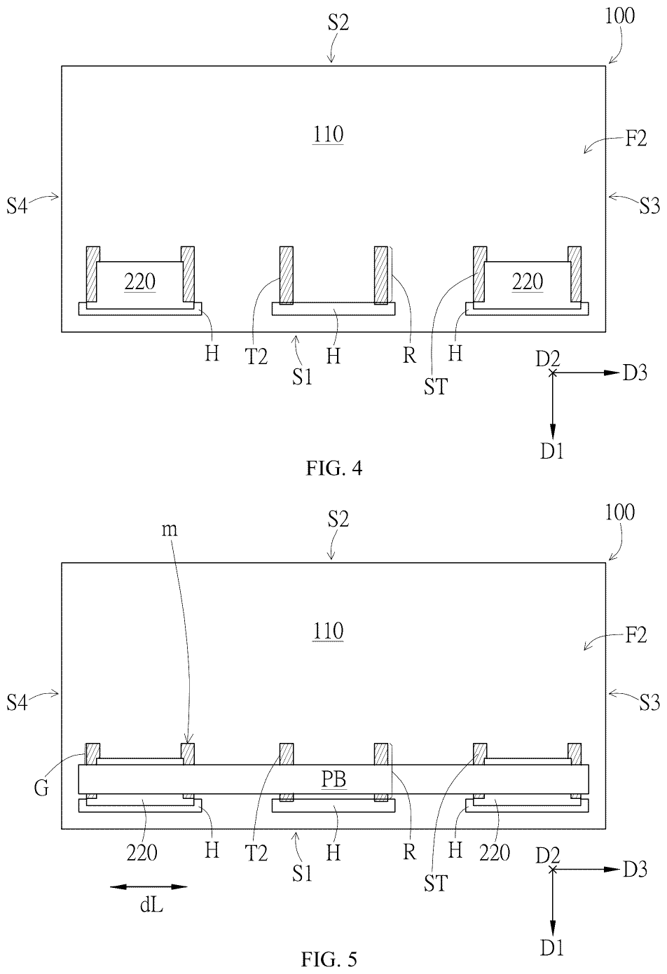

As described above, further referring to the configurations as shown in FIG. 4 (with the circuit substrate PB not yet being installed) and FIG. 5 (with the circuit substrate PB being installed) on the back surface F2 of the bottom plate 110 of the back frame 100, according to certain embodiments, in addition to the predetermined adhering and bonding of the circuit substrate PB, at least a portion of the second section T2 of the stretch release adhesive tape ST may also be used to adhere and bond the back frame 100 and the at least one first flexible circuit board 220. However, the configuration as shown herein is merely an exemplary example, and other embodiments of the present disclosure are not limited thereto. For example, the first flexible circuit board 220 may be adhered and bonded to the back surface F2 by at least a portion of the second section T2 of the stretch release adhesive tape ST, or may be adhered and bonded to the back surface F2 by other intermediary materials such as adhesive tapes or glue dots, or it is possible that the first flexible circuit board 220 is not directly adhered and bonded to the back surface F2, and is instead pressed and positioned by the circuit substrate PB adhered and bonded on the back surface F2. Alternatively, a combination of one or more of the aforementioned configurations may be adopted.

Further referring to FIGS. 4 and 5, according to the present embodiment, the second section T2 of the folded stretch release adhesive tape ST may be disposed on the back surface F2 of the bottom plate 110, and the folded first flexible circuit board 220 may be disposed on the back surface F2 of the bottom plate 110 and may partially overlap with the second section T2 and cover the second section T2. As shown in FIG. 5, when the circuit substrate PB is disposed on the back surface F2 and adhered and bonded to the back surface F2 by the second section T2, at least a portion of the first flexible circuit board 220 may be sandwiched between the back frame 100 and the circuit substrate PB, and may be further electrically connected to the circuit substrate PB. As described above, according to certain embodiments, the first flexible circuit board 220 may be electrically connected to the light source module 210 and the circuit substrate PB. Therefore, with the configuration of the present embodiment, the positioning of the light source module 210, the circuit substrate PB and the first flexible circuit board 220 may be further accomplished using the simplified structure of the stretch release adhesive tape, and the simplified positioning structure may realize the electrical connection between the circuit substrate PB and the first flexible circuit board 220.

According to certain embodiments, as shown in FIGS. 4 and 5, a length direction dL of the circuit substrate PB may extend along a portion of the first side edge S1 and intersect with the extending direction of the stretch release adhesive tape ST, such as the second section T2. With this configuration, the circuit substrate PB may, along the length direction dL (corresponding to the third direction D3) thereof, be sequentially adhered and bonded by multiple strips of the stretch release adhesive tapes ST extending along intersecting extending directions (corresponding to the first direction D1).

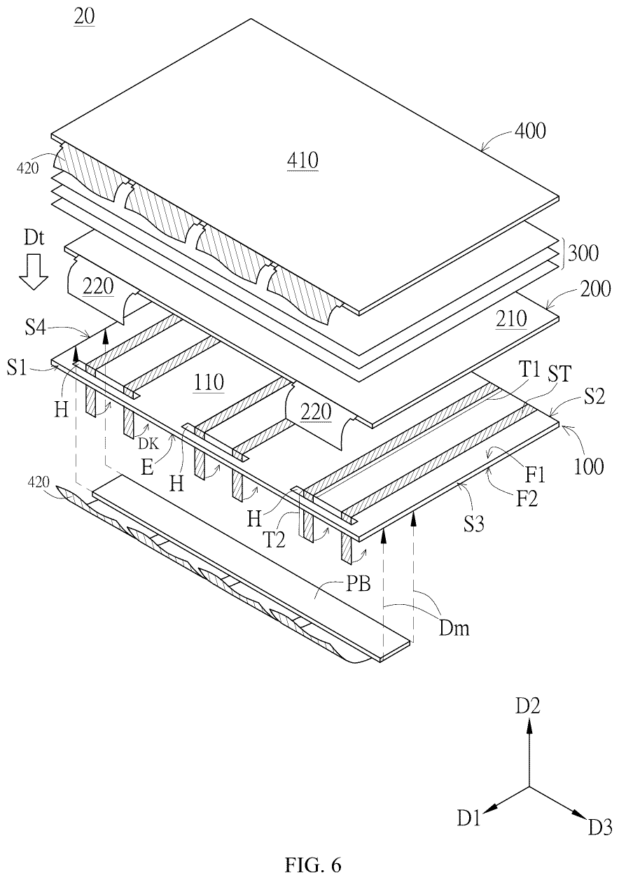

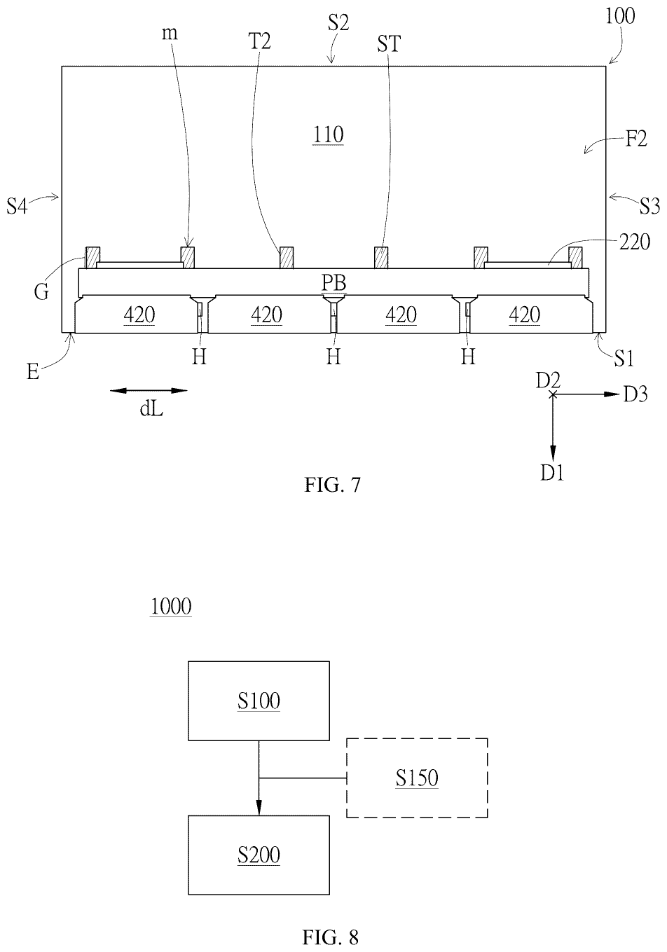

Subsequently, referring to FIGS. 6 and 7, an electronic device according to another embodiment of the present disclosure may have the configuration similar to the electronic device 10 as shown in FIGS. 1 to 5, and the difference exists in the details of further descriptions of the functional module 400. Specifically, as shown in FIG. 6, according to the present embodiment, the functional module 400 includes a panel module 410 disposed on a surface of the light emitting module 200 away from the back frame 100 and at least one second flexible circuit board 420 electrically connected to the panel module 410. In this configuration, the back frame 100 may similarly at least include a bottom plate 110, and the bottom plate 110 has a front surface F1 facing toward the panel module 410 and a back surface F2 away from the panel module 410. The second flexible circuit board 420 may further be connected to the circuit substrate PB. As described above, the second flexible circuit board 420 connected to the panel module 410 and the second flexible circuit board 420 connected to the circuit substrate PB may substantially be a region being integrally formed or an integrated region. However, for illustration clarity, the second flexible circuit board 420 is shown in FIG. 6 as being divided into a portion connected to the panel module 410 and a portion connected to the circuit substrate PB.

As described above, the circuit substrate PB connected to the second flexible circuit board 420 may, similar to the previous embodiment referring to FIGS. 1 to 5, be adhered and bonded to the back surface F2 of the bottom plate 110 of the back frame 100 by the second section T2 of the stretch release adhesive tape ST based on the installation direction Dm. Thus, the at least one second flexible circuit board 420 electrically connected to the circuit substrate PB may wrap around a side edge E of the bottom plate 110 from the panel module 410 and fold to the back surface F2, thus being positioned on the back surface F2 together with the circuit substrate PB when the circuit substrate PB is positioned on the back surface F2. As described above, based on this structural configuration, the light source module 210, the circuit substrate PB, the first flexible circuit board 220 and the second flexible circuit board 420 may be simultaneously positioned and integrated. In addition, the second flexible circuit board 420 may thus be connected to the panel module 410 disposed on the light source module 210 and the circuit substrate PB disposed below the bottom plate 110. Therefore, the simplified structure of the present embodiment may achieve preset electrical connections between the circuit substrate PB, the first flexible circuit board 220 and the second flexible circuit board 420, as well as other modules in the electronic device 20, such as the panel module 410.

Although in FIGS. 6 and 7, the second flexible circuit board 420 is directly connected to the circuit substrate PB, in some other embodiments of the present disclosure, the second flexible circuit board 420 may also be indirectly connected to the circuit substrate PB through other components, such as via an additional connector. As described above, in other embodiments of the present disclosure, additional components or structures may be disposed between the second flexible circuit board 420 and the circuit substrate PB, such that an electrical connection is established between the second flexible circuit board 420 and the circuit substrate PB, and those skilled in the art should understand these variations from the above description. Therefore, these details will not be further reiterated herein.

In addition, according to the present embodiment, the functional module 400 may be a display module to facilitate a display function, and the panel module 410 may be a display panel. However, other embodiments of the present disclosure are not limited thereto.

Further referring to FIG. 7, in certain embodiments, a protruding portion G of the second section T2 extending away from the tail end portion m of the first section T1 may extend and protrude out of the circuit substrate PB without adhering and bonding to the circuit substrate PB. As described above, the configuration may further improve the convenience during reworking, and will be further explained in details with reference to other accompanying drawings.

Next, a reworking method for the electronic device according to one embodiment of the present disclosure will be described with reference to the electronic device 20 as shown in FIGS. 6 and 7 as an exemplary configuration. Those skilled in the art should be able to apply these descriptions correspondingly to the electronic device 10 and potential variations according to other embodiments of the present disclosure.

As described above, with reference to the electronic device 20 in FIGS. 6 and 7, referring to FIG. 8, the reworking method 1000 for the electronic device according to one embodiment of the present disclosure includes the following steps: step S100, where the circuit substrate PB can be disassembled from the back frame 100; and step S200, where the light source module 210 can be separated from the back frame 100. In addition, in certain embodiments, depending on the configuration of the functional module 400, a step S150 may be added between the steps S100 and S200. In the step S150, as the circuit substrate PB is separated from the back frame 100, the at least one second flexible circuit board 420, which is directly or indirectly connected to the circuit substrate PB, and the functional module 400 may be separated from the back frame 100.

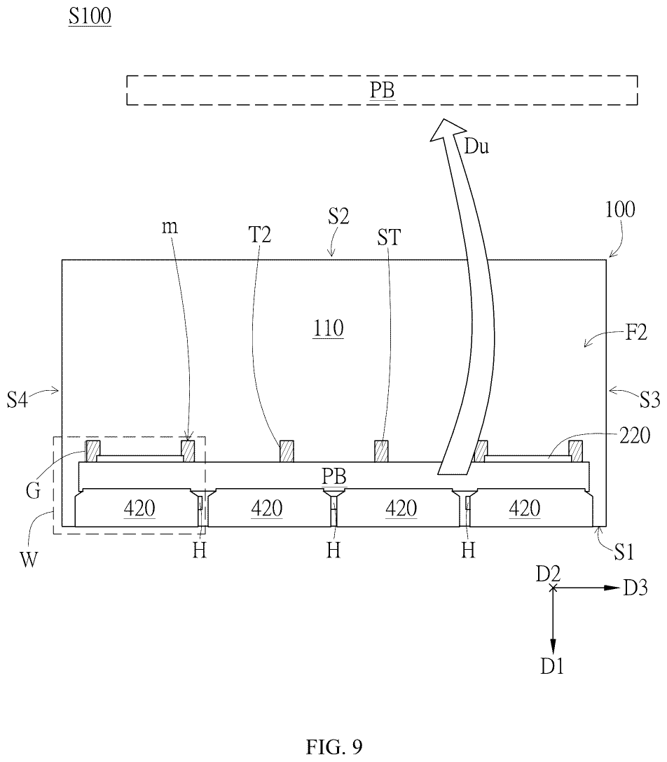

Next, the details of these steps will be specifically described with reference to FIGS. 9 to 14.

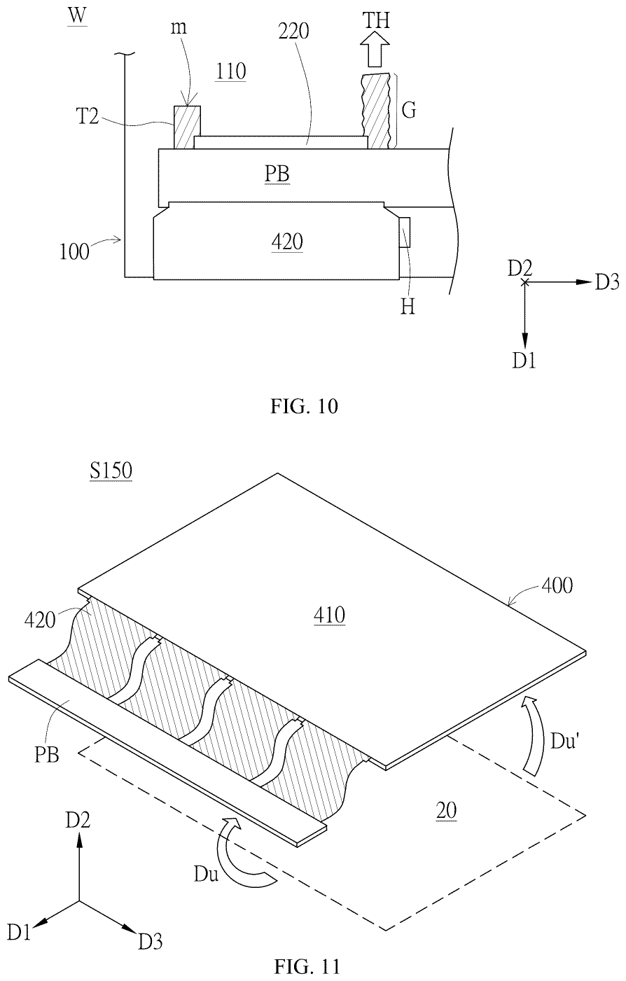

Firstly, referring to FIG. 9 and FIG. 10 which is an enlarged schematic view of a region W of FIG. 9, in the step S100, the circuit substrate PB is disassembled from the back frame 100. For example, according to the present embodiment, a protruding portion G of the second section T2 of at least one stretch release adhesive tape ST extending away from the tail end portion m of the first section T1 extends and protrudes out of the circuit substrate PB without adhering and bonding the circuit substrate PB and the back frame 100. Based on this configuration, the disassembling of the circuit substrate PB may further include stretching TH the protruding portion G as a starting point, thus making it more convenient to stretch and remove the stretch release adhesive tape ST. By stretching TH the protruding portion G, the adhesiveness of at least a portion of the second section T2 adhering and bonding the back frame 100 and the circuit substrate PB may be at least partially reduced, thus allowing the disassembling Du of the circuit substrate PB, thereby separating it from the back frame 100.

According to some other embodiments of the present disclosure, it is possible that no protruding portion G is provided, and a force may be directly applied to disassemble Du the circuit substrate PB when the second section T2 is connected to the circuit substrate PB. Once the disassembling Du of the circuit substrate PB is complete, a portion of the second section T2, which was previously covered by the circuit substrate PB, may be stretched and removed as the starting point, thus making it easier to remove the light source module 210 located on the other surface in the subsequent steps.

Further, as described above, if the electronic device 20 as shown in FIGS. 6 and 7 is used as an example to describe the reworking method 1000 according to the present embodiment, the method may further include the step S150 for disassembling the functional module 400. For example, referring to FIG. 11, according to one embodiment, in the step S150, the reworking method 1000 may disassemble the panel module 410 on the light source module 210 between the disassembling of the circuit substrate PB and the disassembling of the light source module 210. In particular, since the second flexible circuit board 420 is connected to the circuit substrate PB and the second flexible circuit board 420 is also connected to the panel module 410, as the circuit substrate PB separates from the back frame 100, the second flexible circuit board 420 and the panel module 410 connected thereto may also be separated. Therefore, in the step S150, in the disassembling Du of the circuit substrate PB, the panel module 410 can be disassembled Du′ from the electronic device 20 based on the separation of the at least one second flexible circuit board 420, thereby completing the disassembling of the functional module 400.

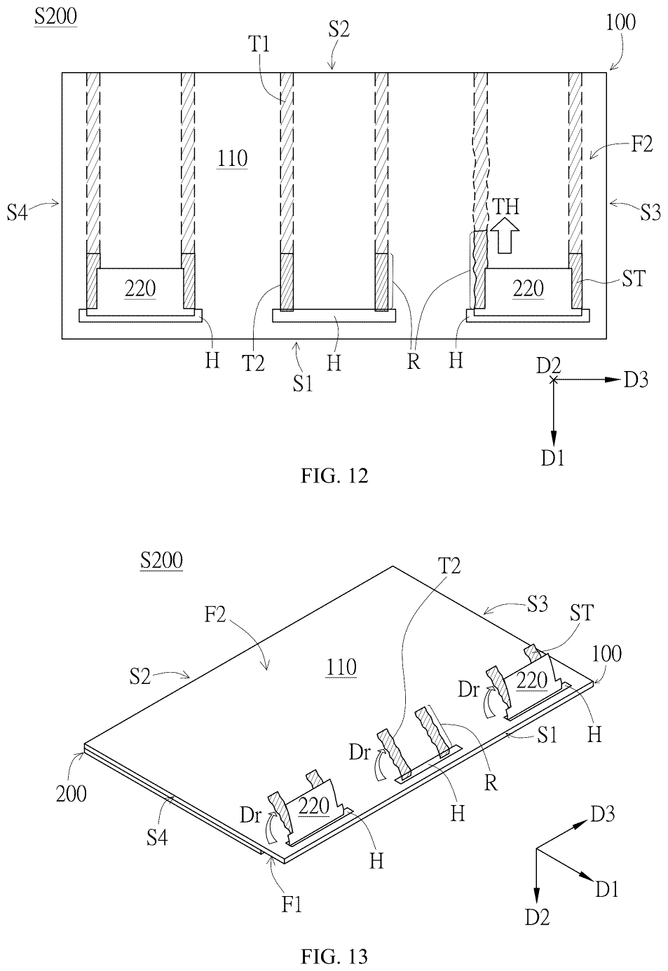

Referring to FIGS. 12 and 13, according to the present embodiment, after completing the step S100 and the optional step S150, a predetermined region R of the second section T2 of the at least one stretch release adhesive tape ST is exposed on the back surface F2 of the bottom plate 110 of the back frame 100. As described above, in the subsequent step S200, by stretching TH the predetermined region R located on the back surface F2 of the bottom plate 110, the adhesiveness of at least a portion of the first section T1 of the at least one stretch release adhesive tape ST located on the front surface F1 of the bottom plate 110 is at least partially reduced, thus allowing separation of the light source module 210 disposed on the front surface F1 and the back frame 100.

As shown in FIGS. 12 and 13, as the overall adhesiveness of the stretch release adhesive tape ST is reduced, it becomes easy to disassemble Dr the stretch release adhesive tape ST from the back surface F2 of the bottom plate 110 of the back frame 100. As described above, in certain embodiments, the first flexible circuit board 220 is electrically connected to the light source module 210 and the circuit substrate PB, and may be partially adhered and bonded to the back frame 100 by at least a portion of the second section T2 of the at least one stretch release adhesive tape ST. Therefore, in this process, the first flexible circuit board 220 may also be disassembled Dr from the back surface F2. Alternatively, if no portion of the second section T2 is used to adhere and bond the first flexible circuit board 220, the first flexible circuit board 220 may be directly flipped open to expose a portion of the second section T2, and by stretching TH the portion of the second section T2, the adhesiveness of the stretch release adhesive tape ST may be reduced, thus making it easier to disassemble the first flexible circuit board 220 and the light source module 210 connected thereto in the subsequent steps.

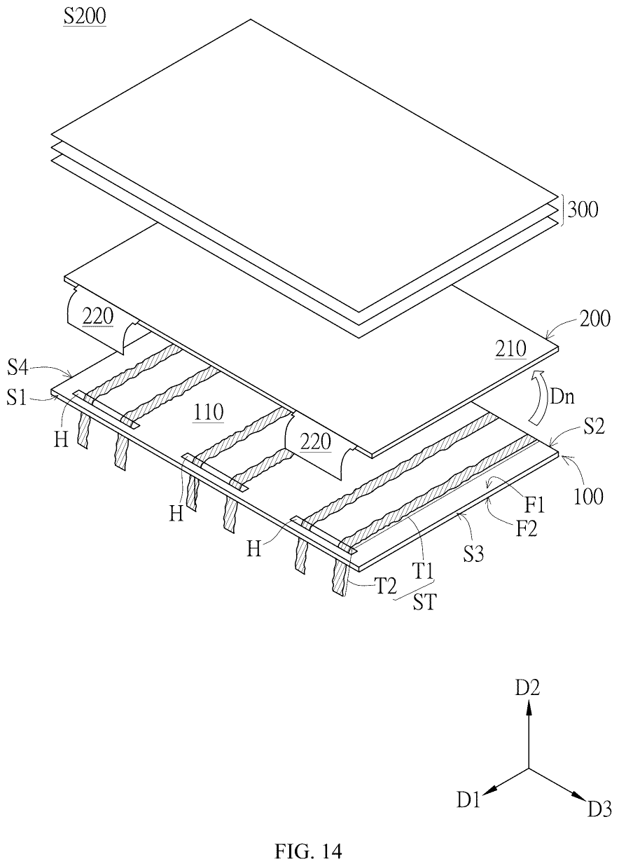

Next, referring to FIGS. 12 and 13, as well as FIG. 14 which illustrates the state of the front surface F1 of the bottom plate 110, in the step S200, the stretching of the second section T2 of the stretch release adhesive tape ST causes the adhesiveness of at least a portion of the first section T1 to be reduced, and the first flexible circuit board 220 connected to the light source module 210 also separates from the back frame 100 and can be removed through the through hole H. Thus, the light source module 210 connected to the back frame 100 by the first section T1 of the stretch release adhesive tape ST may be disassembled Dn from the back frame 100.

As described above, in the step S200, the disassembling of the light source module 210 may include stretching the predetermined region R to at least partially reduce the adhesiveness of the second section T2, thereby separating the back frame 100 and the at least one first flexible circuit board 220. Based on the separation of the at least one first flexible circuit board 220 and the reduction of the adhesiveness of the first section T1, the light source module 210 is disassembled Dn from the back frame 100. In addition, in the case where one or more optical films 300 are provided, these optical films 300 may be disassembled either before or during the disassembling of the light source module 210. Therefore, according to the present embodiment, the disassembling and reworking of the electronic device 20 may be achieved in a simplified manner by reducing or avoiding damages to the components and/or modules of the electronic device 20.

As described above, in the electronic device and the reworking method for the same according to embodiments of the present disclosure, the positioning and connection of various components or modules may be integrated with reduced or simplified positioning members. Thus, makes the disassembly and rework process more convenient and increases the success rate. Therefore, the electronic device and the reworking method for the same according to embodiments of the present disclosure may help build the electronic device with reduced materials, and may help improve the disassembling and reworking processes and increase the material recovery rate after disassembling and reworking, thereby further enhancing the efficiency of repair or recycling. As described above, the embodiments of the present disclosure may contribute to a more environmentally friendly manufacturing process for the electronic device, and may assist in realizing a circular economy.

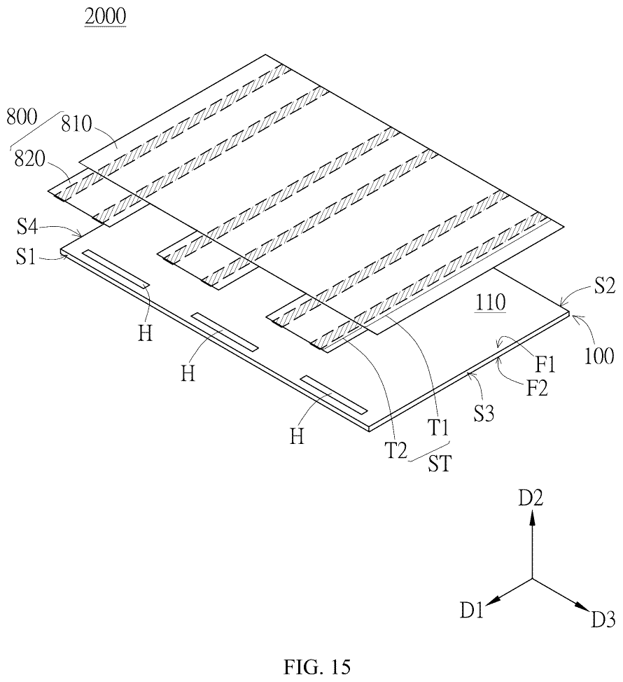

Next, referring to FIGS. 15 to 18, an exemplary embodiment of the structure of the stretch release adhesive tape of the electronic device and the components and modules positioned by the stretch release adhesive tape according to one embodiment of the present disclosure is described.

Firstly, referring to FIG. 15, in the method 2000 according to one embodiment, a stretch release adhesive tape ST may be disposed on a release film 800. As described above, the stretch release adhesive tape ST may be an adhesive tape with adhesiveness on both sides, and one side thereof facing the release film 800 may be firstly adhered on a lower surface of the release film 800 as shown in FIG. 15. Specifically, the release film 800 may have a first portion 810 and a second portion 820, where the first portion 810 corresponds to the first section T1 of the stretch release adhesive tape ST, and the second portion 820 corresponds to the second section T2 of the stretch release adhesive tape ST. The first portion 810 of the release film 800 may be peeled off independently from the second portion 820, and the second portion 820 may also be peeled off independently from the first portion 810.

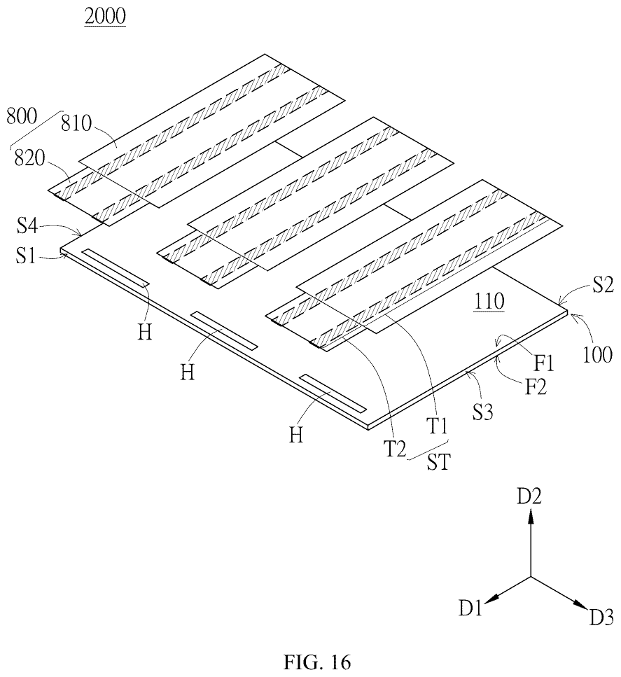

As described above, the first portion 810 and the second portion 820 of the release film 800 in FIG. 15 may be peeled off independently. In addition, although the entire release film 800, which has not yet been peeled off in the embodiment as shown in FIG. 15, is integrated as a complete piece, such that the process of placing the stretch release adhesive tape ST is simpler, other embodiments of the present disclosure are not limited thereto. For example, as shown in FIG. 16, in certain embodiments of the present disclosure, for a stretch release adhesive tape ST predetermined to correspond to a light source module 110, multiple release films 800 may be used, and each separate release film 800 may be aligned and adjusted individually, thus allowing for more precise positioning of the stretch release adhesive tape ST and making it easier to disassemble individual portions of the release films 800.

Next, the process of disposing the stretch release adhesive tape ST will be further described with reference to the configuration as shown in FIG. 16.

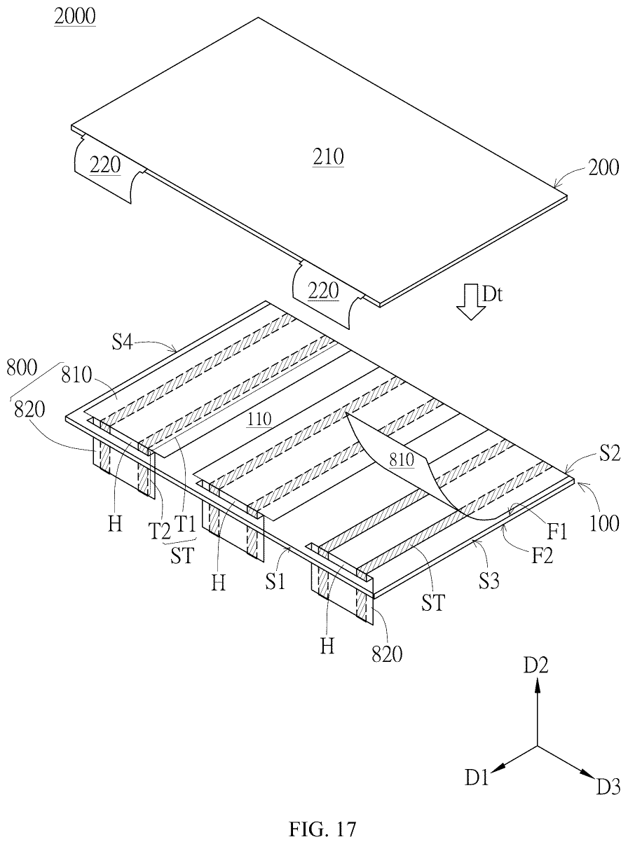

As shown in FIG. 17, the first section T1 of the stretch release adhesive tape ST, which is disposed on the lower surface of the release film 800, may be aligned with the front surface F1 of the bottom plate 110 for adhering the first portion 810 of the release film 800. After completing the adhesion, the corresponding first portion 810 may be peeled off, thus exposing the adhesive surface of the first section T1 of the stretch release adhesive tape ST away from the bottom plate 110. Thus, the adhesive surface of the exposed first section T1 may be used for adhering and bonding the light source module 210.

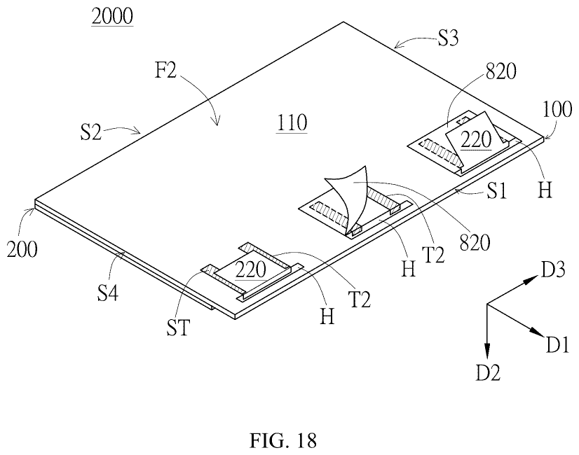

Next, referring to FIGS. 17 and 18, the second portion 820 of the release film 800 and the second section T2 of the stretch release adhesive tape ST thereon may pass through the through hole H to be folded. The folded second portion 820 allows one surface of the second section T2 facing the back surface F2 of the bottom plate 110 to be adhered on the back surface F2. Then, as shown in FIG. 18, the second portion 820 of the release film 800, now adhered to the back surface F2 by the second section T2, may be peeled off to expose the adhesive surface of the second section T2 away from the bottom plate 110. Thus, the adhesive surface of the exposed second section T2 may be used for adhering and bonding subsequent components, such as the circuit substrate PB or the first flexible circuit board 220 connected to the light source module 210. As described above, this may complete the disposing of the stretch release adhesive tape ST in the configuration according to the embodiments of the present disclosure as well as the disposing/adhesion/positioning of other corresponding component or modules. According to the present embodiment, the extending direction of the stretch release adhesive tapes ST arranged in parallel may intersect with the length direction of the circuit substrate PB to be adhered and bonded, such that multiple strips of the stretch release adhesive tapes ST extending and folded from the front surface F1 of the bottom plate 110 to the back surface F2 may be arranged side-by-side to more securely adhere the circuit substrate PB.

The exemplary embodiment of the disposing of the stretch release adhesive tape according to embodiments of the present disclosure has been described with reference to FIGS. 15 to 18. However, the method for disposing the stretch release adhesive tape in other embodiments of the present disclosure is not limited thereto. Those skilled in the art should understand that, based on the positioning configuration for the stretch release adhesive tape in the electronic device according to the embodiments of the present disclosure, various methods may be used for disposing the stretch release adhesive tape. In addition, after the positioning and configuration of various components and modules are completed, according to certain embodiments of the present disclosure, external packaging tape or the like may also be applied to assist in positioning and encapsulating the overall structure of the electronic device. Those skilled in the art should understand these variations, which are thus not hereinafter reiterated.

In sum, according to the embodiments of the present disclosure, at least a portion of the light emitting module and the circuit substrate may be positioned using the stretch release adhesive tape, thereby simplifying or reducing the positioning components in the electronic device, and correspondingly improving and simplifying the disassembly and reworking of the electronic device. Therefore, the electronic device and the reworking method for the same according to the embodiments of the present disclosure may integrate the positioning of various components and/or modules of the electronic device, reducing the complexity or difficulty of the reworking. In addition, due to the improvement and simplification of the reworking process, the possibility of damages of the components or modules during reworking process may be reduced or avoided, thereby enhancing the repairability and reusability of the components or modules. Further, since the disassembly and reworking are made easier, the efficiency of recycling and sorting individual materials may be improved, thus reducing or preventing situations where materials are difficult to sort and thus hard to process or recycle. Therefore, the electronic device and the reworking method of the same according to the embodiments of the present disclosure may enhance resource utilization, reduce waste generation, and thus promote a more environmentally friendly circular economy.

The foregoing description of the exemplary embodiments of the invention has been presented only for the purposes of illustration and description and is not intended to be exhaustive or to limit the invention to the precise forms disclosed. Many modifications and variations are possible in light of the above teaching.

The embodiments were chosen and described in order to explain the principles of the invention and their practical application so as to activate others skilled in the art to utilize the invention and various embodiments and with various modifications as are suited to the particular use contemplated. Alternative embodiments will become apparent to those skilled in the art to which the present invention pertains without departing from its spirit and scope. Accordingly, the scope of the present invention is defined by the appended claims rather than the foregoing description and the exemplary embodiments described therein.

What is claimed is:

1. An electronic device, comprising:
a light emitting module, having a light source module;
a back frame, configured to support the light source module, and having at least one through hole;
at least one stretch release adhesive tape, respectively divided into a first section and a second section along an extending direction, and passing through the at least one through hole to be folded, such that the first section and the second section are respectively located on different sides of the at least one through hole and attached on different surfaces of the back frame facing different directions, wherein at least a portion of the first section adheres and bonds the light source module and the back frame; and
a circuit substrate, wherein at least a portion of the second section adheres and bonds the back frame and the circuit substrate.

2. The electronic device according to claim 1, wherein the light emitting module further comprises at least one first flexible circuit board electrically connected to the light source module, and the at least one first flexible circuit board passes through the at least one through hole from the light source module to be folded, such that the light source module and the at least one first flexible circuit board are respectively located on different sides of the at least one through hole and disposed on different surfaces of the back frame facing different directions, and
wherein at least a portion of the second section adheres and bonds the back frame and the at least one first flexible circuit board.

3. The electronic device according to claim 2, wherein the at least one first flexible circuit board is clamped between the back frame and the circuit substrate, and the at least one first flexible circuit board is electrically connected to the light source module and the circuit substrate.

4. The electronic device according to claim 2, wherein a quantity of the at least one through hole is greater than a quantity of the at least one first flexible circuit board.

5. The electronic device according to claim 1, further comprising a functional module configured to facilitate a predetermined function, wherein the functional module comprises a panel module disposed on a surface of the light emitting module away from the back frame and at least one second flexible circuit board electrically connected to the panel module,
wherein the back frame at least comprises a bottom plate, and the bottom plate has a front surface facing toward the panel module and a back surface away from the panel module,
wherein the second section of the at least one stretch release adhesive tape adheres and bonds the back surface of the bottom plate and the circuit substrate, and
wherein the at least one second flexible circuit board wraps outside a side edge of the bottom plate from the panel module and folds to the back surface, and is electrically connected to the circuit substrate.

6. The electronic device according to claim 5, wherein the functional module is a display module facilitating a display function, and the panel module is a display panel.

7. The electronic device according to claim 1, wherein a quantity of the at least one stretch release adhesive tape is greater than a quantity of the at least one through hole.

8. The electronic device according to claim 1, wherein the light source module is a direct type light emitting panel.

9. The electronic device according to claim 1, wherein the back frame at least has a bottom plate, the bottom plate has a first side edge and a second side edge opposite to each other, and the at least one through hole extends individually along a portion of the first side edge, and
wherein the at least one stretch release adhesive tape extends along a first direction from the second side edge toward the first side edge on a front surface of the bottom plate away from the circuit substrate, and passes through the at least one through hole disposed along the first side edge to be folded to a back surface of the bottom plate on which the circuit substrate is disposed.

10. The electronic device according to claim 1, wherein the back frame at least has a bottom plate, the bottom plate has a first side edge and a second side edge opposite to each other, and a length direction of the circuit substrate extends along a portion of the first side edge, and
wherein the at least one stretch release adhesive tape extends along a first direction from the second side edge toward the first side edge on a front surface of the bottom plate away from the circuit substrate, and passes through the at least one through hole to be folded to a back surface of the bottom plate on which the circuit substrate is disposed.

11. The electronic device according to claim 1, wherein a length of the first section is greater than a length of the second section.

12. The electronic device according to claim 1, wherein a protruding portion of the second section extending away from a tail end portion of the first section extends and protrudes out of the circuit substrate without adhering and bonding to the circuit substrate.

13. A reworking method for the electronic device according to claim 1, comprising:
disassembling the circuit substrate from the back frame, and exposing a predetermined region of the second section of the at least one stretch release adhesive tape; and
stretching the predetermined region to at least partially reduce an adhesiveness of the first section of the at least one stretch release adhesive tape connected to the predetermined region, thereby separating the light source module and the back frame.

14. The reworking method according to claim 13, wherein a protruding portion of the second section of the at least one stretch release adhesive tap extending away from a tail end portion of the first section extends and protrudes out of the circuit substrate, and
wherein the disassembling the circuit substrate further comprises stretching the protruding portion to at least partially reduce an adhesiveness of the portion of the second section adhering and bonding the back frame and the circuit substrate, thereby separating the back frame and the circuit substrate.

15. The reworking method according to claim 13, wherein the light emitting module further comprises at least one first flexible circuit board electrically connected to the light source module and the circuit substrate, and the at least one first flexible circuit board passes through the at least one through hole from the light source module to be folded, such that the at least one first flexible circuit board and the light source module are disposed on different surfaces of the back frame facing different directions, and
wherein the at least one first flexible circuit board partially adheres and bonds on the back frame by a portion of the second section of the at least one stretch release adhesive tap, and
wherein the stretching the predetermined region further comprises stretching the predetermined region to at least partially reduce an adhesiveness of the second section, thereby separating the back frame and the at least one first flexible circuit board, and disassembling the light source module from the back frame based on the separating of the at least one first flexible circuit board.

16. The reworking method according to claim 13, wherein the electronic device further comprises a functional module configured to facilitate a predetermined function, wherein the functional module comprises a panel module disposed on a surface of the light emitting module away from the back frame and at least one second flexible circuit board electrically connected to the panel module,
wherein the at least one second flexible circuit board is electrically connected to the panel module and the circuit substrate, and
wherein the reworking method further comprises, between the disassembling the circuit substrate and stretching the predetermined region: with the circuit substrate being separated from the back frame, separating the at least one second flexible circuit board directly or indirectly connected to the circuit substrate from the back frame, and disassembling the panel module from the electronic device based on the separating of the at least one second flexible circuit board.
